(19) United States
(12) Patent Application Publication
(10) Pub. No.: US 2006/0145140 A1
(43) Pub. Date: Jul. 6, 2006

(54) Organic field effect transistor and integrated circuit

(76) Inventors: Walter Fix, Nurnberg (DE); Andreas Ullmans, Zirndorf (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/541,957

(22) PCT Filed: Dec. 8, 2003
(86) PCT No.: PCT/DE03/04036

§ 371 Date: Feb. 2, 2006

(30) Foreign Application Priority Data
Jan. 14, 2003 (DE) 103 01 086.6

(51) Int. Cl. H01L 29/08

(52) U.S. Cl. 257/40

(57) ABSTRACT

Organic field effect transistor and integrated circuit The invention relates to an organic field effect transistor (OFET) and/or to an organically based integrated circuit having a high switching frequency. Joining the two ends of the current channel results in compact and fast circuit layouts.

Organic field effect transistor and integrated circuit The invention relates to an organic field effect transistor (OFET) and/or to an organically based integrated circuit having a high switching frequency.

Organically based integrated circuits having a ring oscillator layout, for example, are known, the layout not being optimized at all, however, as regards the switching frequency of organic circuits (W. FIX et al., Appl. Phys. Lett., 81, 1735 (2002)).

The disadvantage of the known layout for organic electronics is that no organic interconnects are provided.

The circuit layouts from silicon electronics cannot be adopted easily since adapted layouts are required on account of the special electrical properties of the organic materials. The interconnect resistance thus plays virtually no role in conventional integrated circuits since use is made of metals which have a negligibly small resistance in comparison with organic conductors. If organic interconnects are used, the width and length of these interconnects and the arrangement of the individual components play an important role.

In an effort to provide a digital circuit based on organic electronics, the object is to redesign the basic modules of all digital circuits such as a transistor, an inverter and a NAND or NOR gate and to provide a suitable layout for them.

The invention therefore relates to an organic field effect transistor, which comprises at least a first electrode layer having source and drain electrodes, a semiconducting layer, an insulator layer and a second electrode layer, and in which one of the electrodes (source or drain) in the first electrode layer surrounds the respective other electrode in a two-dimensional manner with the exception of one side or location (the connection side or location) of this electrode, with the result that a current channel, which begins and ends on one side or at one location of an electrode of the first electrode layer, can be formed.

In this case, layout is understood as meaning the form and arrangement of the electrodes, interconnect crossover points and through-contacts (=vertical connection of interconnects which are situated in different planes). The layout determines series resistances and parasitic capacitances which have a substantial effect on the switching speed and also on the functionality of the integrated circuit.

In accordance with one embodiment of the invention, the source electrode bounds the drain electrode of each organic field effect transistor (OFET) used on three sides and the respective electrode that is surrounded, the drain electrode (the drain and source may, of course, also be interchanged), is then open only on one side and has a connection only on one side, that is to say the current channel, which is formed after the gate voltage has been applied, begins and ends on the same side of the electrode (the connection side) and is, for example, u-shaped or meandering.

In accordance with another embodiment that is preferably combined with the embodiment described above, the OFETs are arranged in the NAND or NOR gate in such a manner that the connection sides are respectively opposite one another. To this end, in the NAND and/or NOR gate, two or more OFETs are respectively parallel (two or more u-shaped channels next to one another in the NOR gate) or are interleaved in one another (two or more u-shaped channels inside one another in the NAND gate). In this case, the connecting lines and/or the inputs and outputs are respectively preferably situated in the region between the connection sides.

In accordance with another embodiment, the gate electrode additionally covers a small part of the source or drain electrode in addition to covering the entire channel. In this case, the current channel is completely covered and, in addition, at least one other part of one or both of the first electrodes is covered, this additionally covered part having a width in the range from 0 to 20 μm and having a length in the range of the length of the current channel. The width of the covered part depends on the alignment accuracy of the production technology and is in the range from a few (0 to 8) μm to approximately 20 μm, preferably 1 to 5 μm.

In accordance with one embodiment, holes or interruptions which reduce leakage currents between the OFETs are provided in the semiconductor layer. These holes are preferably situated between the connection sides. These subsequently produced holes or interruptions are used to reduce leakage currents which are produced as a result of unintentional background doping or contamination of the semiconductor layer that is typically unpatterned and covers the entire chip.

Another different embodiment provides for use to be made of a through-contact, which is additionally connected to the output of the inverter, instead of an electrical connection that is sometimes required between the gate electrode and the drain electrode of a load OFET. This makes it possible to dispense with at least one through-contact. One through-contact is typically required for the gate-drain connection of the load FET and another is required at the inverter output for the connection to the following inverter/logic gate; these two through-contacts can be joined the suitable layout.

In accordance with another embodiment, in the event of an electrical connection between the gate electrode and the source electrode of a drive OFET being required for the circuit, the through-contact is preferably formed in such a manner that it extends as far as one or both sides of the OFET. As a result, a plurality of cascaded inverters, NAND gates or NOR gates have a joint through-contact.

The layout described here affords a number of advantages:

Faster integrated circuits: optimum use of the area for the organic electrodes and the very short connecting lines result in low series resistances and thus higher switching speeds. The shortness of the connecting lines, the reduction in the number of interconnect crossings required and minimization of the gate electrode considerably reduce the parasitic capacitance, thus likewise significantly increasing the switching speed.

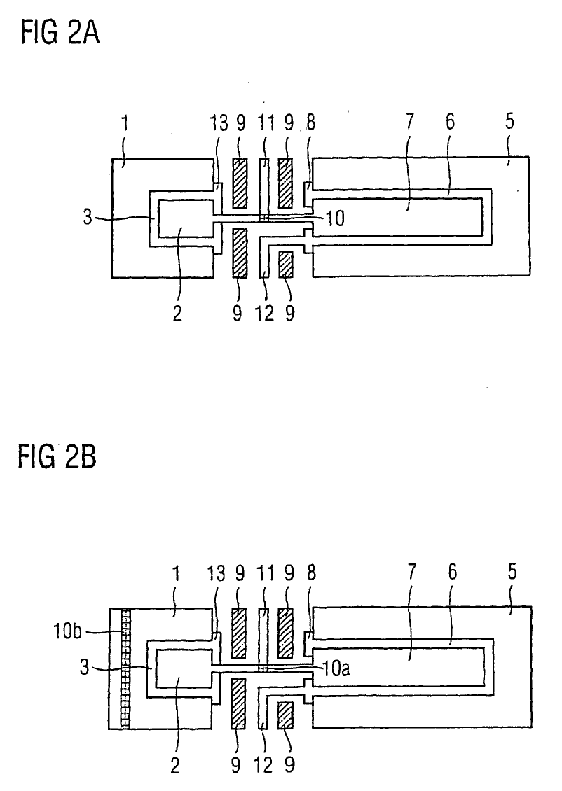

More stable circuits and lower power consumption as a result of minimizing the leakage currents: the leakage currents are minimized, on the one hand, by the arrangement of the electrodes and, on the other hand, by the holes in the semiconductor layer. The arrangement of the electrodes completely suppresses leakage currents between various inverters and NAND or NOR gates since adjacent electrodes are respectively at the same electrical potential (supply voltage or ground), which, in turn, results from the fact that an OFET electrode surrounds and shields the respective other electrode with the exception of one side or location. By way of example, in FIG. 2a), the electrode 5 is at ground, electrode 1 is at the supply voltage and two directly adjacent inverters (lying one above the other in the figure) then come into contact only with electrodes which are at the same potential (cf. FIG. 5 as well).

In addition, leakage currents within an inverter or gate are prevented by means of holes in the semiconductor layer. Virtually no leakage current can thus flow between the output 11 and the electrode 1 in FIG. 2b), for example.

According to the invention, circuits can be designed in a considerably easier manner: the inverters and the logic gates can be assembled in a modular manner without having to comply with spacings. In addition, the channel geometries (channel length and width) can be scaled easily without changing the external shape of the OFETs. Finally, the space required by the circuit is smaller and the entire available area can therefore be advantageously used. Finally, joining through-contacts reduces the number thereof (cf. FIG. 5).

The invention will also be explained in more detail below with reference to individual embodiments:

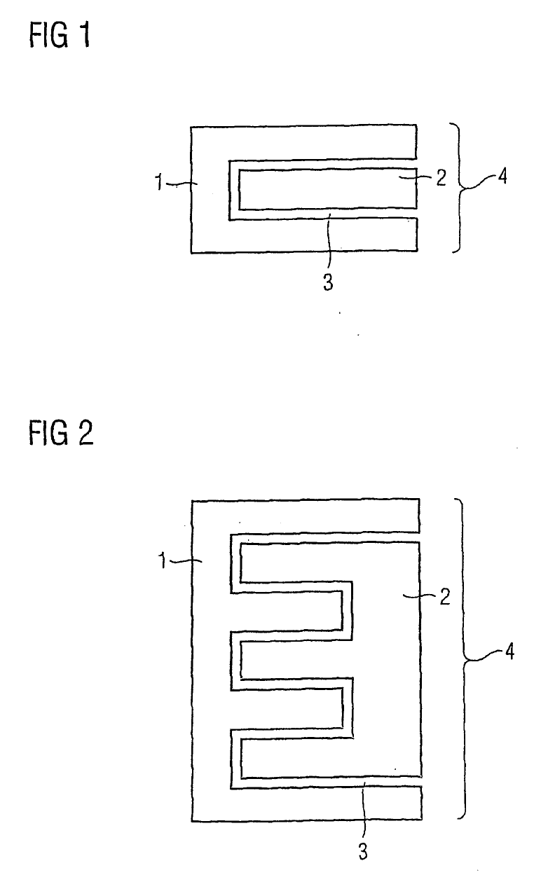

FIG. 1 shows two layouts for an OFET;

FIG. 2 shows two layouts for an inverter;

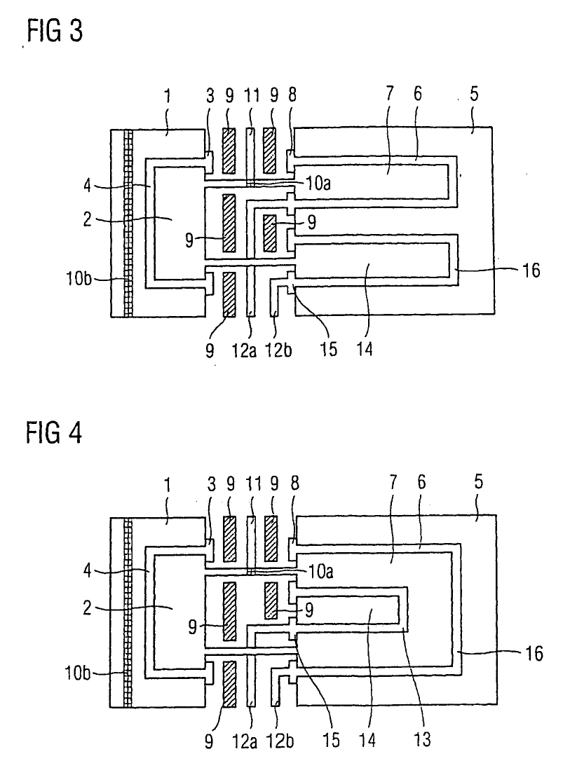

FIG. 3 shows one layout for a two-input NOR gate;

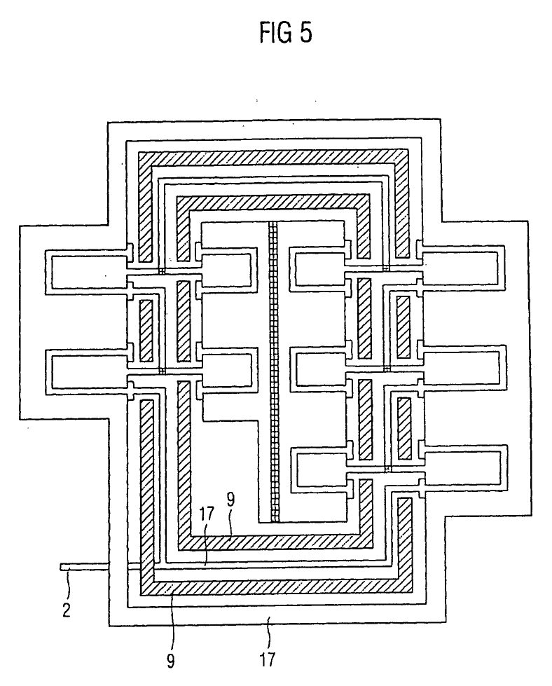

FIG. 4 shows one layout for a two-input NAND gate; and

FIG. 5 shows one layout for a five-stage ring oscillator.

FIG. 1 shows an OFET having a first electrode 1 (source or drain) and a second electrode 2 (drain or source), the first electrode 1 surrounding the second electrode 2 with the exception of one side or on three of four sides. Only the connection side 4 of the OFET remains, the first electrode 1 not surrounding the second electrode 2 on said connection side.

FIG. 1a) shows the simplest embodiment, in which a U-shaped current channel (OFET channel 3) is formed, and FIG. 1b) shows a somewhat more elaborate embodiment, in which a meandering OFET channel 3 is formed.

FIG. 2 shows two layouts for an inverter:

There are, in principle, two possible ways of connecting an inverter and these are distinguished by the manner in which the gate electrodes of the load OFET are connected. Both variants can be expediently used in circuits. The layouts shown in FIG. 2 are embodiments of the invention in accordance with these two variants.

FIG. 2a) shows an inverter having a load OFET at the output: the inverter comprises two OFETs, the load OFET and the drive OFET. The source electrode 1 of the load OFET surrounds the drain electrode 2 of the load OFET on three sides and an OFET channel 3, which is covered by the gate electrode 13 of the load OFET, is produced, another part of the source electrode 1 and of the drain electrode 2 of the load OFET also being concomitantly covered. In addition, the gate electrode 13 is connected not only to the source electrode 2 but also to the output 11 and to the source electrode 7 of the drive OFET via the through-contact 10. The gate electrode 8 of the drive OFET covers the channel 6 of the drive OFET and is connected to the input 12. The drain electrode 5 of the drive OFET surrounds the source electrode 7 and thus defines the channel 6. The holes or interruptions 9 in the semiconductor layer are situated between the load and drive OFETs and prevent leakage currents. The supply voltage is applied to electrode 1 and electrode 5 is at ground. These two electrodes surround virtually the entire inverter and thereby shield it from other components. When changing over the inverter, only the potential of electrode 2 or 7 changes, said electrodes being connected to one another and being situated in the interior of the inverter.

The electrical connection, which, depending on the circuit, is required between the gate electrode 13 and the drain electrode 2 of the load OFET, is implemented using a through-contact 10 that is additionally connected to the output 11.

The example of an inverter shown in FIG. 2b) has the load OFET gate at the supply voltage. The design is analogous to that from FIG. 2a). In contrast to 2a), the gate electrode 13 is connected, in this case, to the source electrode 1 by means of the through-contact 10a and not, as in 2a), to the through-contact 10a to the output 11. The through-contact 10b is elongated as far as the edge of electrode 1, thus having the advantage that inverters which are located next to one another can jointly use the through-contact.

If an electrical connection between the gate electrode 13 and the source electrode 1 of an OFET is required for the circuit, the through-contact is preferably formed in such a manner that it extends as far as the sides of the OFET. As a result, a plurality of cascaded inverters, NAND gates or NOR gates have a joint through-contact.

FIG. 3 shows one layout for a two-input NOR gate: the layout essentially corresponds to that of the inverter from FIG. 2b) with the difference that two drive OFETs are connected in parallel. The second drive OFET comprises the source electrode 14 and has a joint drain electrode 5 with the first drive OFET. The gate electrode 15 of the drive OFET is connected to the second input 12b of the NOR gate. The entire NOR gate is shielded by the two electrodes 1 and 5 which are at the supply voltage or ground.

FIG. 4 shows a two-input NAND gate. The NAND layout likewise essentially corresponds to the inverter from FIG. 2b) with the difference that two drive OFETs are connected in series. The second drive OFET is surrounded by the first on three sides. The source electrode 7 of the first drive OFET is simultaneously the drain electrode of the second drive OFET. The source electrode 14 determines the channel 16 of the second drive OFET and is covered by the gate electrode 15, which is connected to the second input 12a. In this layout too, there is shielding by the electrodes 1 and 5.

Finally, FIG. 5 shows a five-stage ring oscillator comprising five inverters which are designed as shown in FIG. 2b. The inverters are arranged in such a manner that, in the center, a joint through-contact 10 (10b) can be used for all of the inverters. In addition, the inverters are arranged in such a manner that they butt against one another directly, this only being possible as a result of the layout according to the invention. The inverters are connected at the ends by means of the connecting lines 17 and the holes or interruptions in the semiconductor 9 are also continued between the connecting lines in order to prevent leakage currents. The output 11 of the ring oscillator branches off at a connecting line 17.

FIG. 5 impressively shows how circuit layouts are efficiently produced with the aid of the invention. In particular, lines are replaced, in this case, with direct contact, thus leading to a higher switching speed, for example.

The invention relates to an organic field effect transistor (OFET) and/or to an organically based integrated circuit having a high switching frequency. Joining the two ends of the current channel results in compact and fast circuit layouts.

1. An organic field effect transistor (OFET) including a gate, comprising:
at least a first electrode layer forming a source or drain electrode and having multiple sides;
a semiconducting layer
an insulator layer; and
a second electrode layer forming the other of said source and drain electrodes and having multiple sides wherein the source or drain electrode in the first electrode layer surrounds the respective other electrode of the second electrode layer in a two-dimensional manner with the exception of one of said sides the other electrode
whereby a u-shaped and/or meandering current channel which begins and ends on one of said side of the electrode of the first electrode layer, is formed in the semiconducting layer.

2. The OFET as claimed in claim 1 wherein,

2. The OFET as claimed in claim 1 wherein the first electrode layer respectively bounds the other electrode layer on three of four sides.

3. The OFET as claimed in claim 1 wherein the second electrode layer completely covers the current channel of the first electrode layer and, in addition, at least one other part of the first electrode layer, this other additionally covered part having a width in the range from 0 to 20 μm and having a length in the range of the length of the current channel.

4. The OFET as claimed in claim 1 wherein holes and/or interruptions are in the semiconductor layer to reduce leakage currents.

5. An integrated circuit having at least two OFETs as claimed in claim 1 wherein the at least two OFETs are arranged into a NAND or NOR gate such that the one sides of the two OFETs are respectively opposite one another.

6. The integrated circuit as claimed in claim 5 including connecting lines and/or inputs and outputs respectively situated in a region between the one sides

7. The integrated circuit as claimed in claim 5 wherein holes and/or interruptions are in the semiconductor layer.

8. The integrated circuit as claimed in claim 7 wherein the holes and/or interruptions are between the one sides.

9. The integrated circuit as claimed in claim 5 including a through-contact in said first electrode layer.

10. The integrated circuit as claimed in claim 9 wherein the through-contact extends at least to one further side of the OFET other than said one side.

11. The OFET as claimed in claim 2 wherein the second electrode layer completely covers the current channel of the first electrode layer and, in addition, at least one other part of the first electrode layer, this other additionally covered part having a width in the range from 0 to 20 μm and having a length in the range of the length of the current channel.

12. The OFET as claimed in claim 2 wherein holes and/or interruptions are in the semiconductor layer to reduce leakage currents.

13. The OFET as claimed in claim 3 wherein holes and/or interruptions are in the semiconductor layer to reduce leakage currents.

14. An integrated circuit having at least two OFETs as claimed in claim 2 wherein the at least two OFETs are arranged into a NAND or NOR gate such that the one sides of the two OFETs are respectively opposite one another.

15. An integrated circuit having at least two OFETs as claimed in claim 3 wherein the at least two OFETs are arranged into a NAND or NOR gate such that the one sides of the two OFETs are respectively opposite one another.

16. An integrated circuit having at least two OFETs as claimed in claim 4 wherein the at least two OFETs are arranged into a NAND or NOR gate such that the one sides of the two OFETs are respectively opposite one another.

17. The integrated circuit as claimed in claim 14 including connecting lines and/or inputs and outputs respectively situated in a region between the one sides.

18. The integrated circuit as claimed in claim 15 including connecting lines and/or inputs and outputs respectively situated in a region between the one sides.

19. The integrated circuit as claimed in claim 16 including connecting lines and/or inputs and outputs respectively situated in a region between the one sides.

20. The integrated circuit as claimed in claim 17 including connecting lines and/or inputs and outputs respectively situated in a region between the one sides.
